(19) United States
(12) Patent Application Publication
(10) Pub. No.: US 2005/0279523 A1
(43) Pub. Date: Dec. 22, 2005

(54) Hidden radiating fin structure

(75) Inventor: Yung-cheng Chen, Taoyuan City (TW)

Correspondence Address: TROXELL LAW OFFICE PLLC, SUITE 1404, 5205 LEESBURG PIKE, FALLS CHURCH, VA, 22041, US

(73) Assignee: LOYALTY FOUNDER ENTERPRISE CO., LTD.

(21) Appl. No.: 10/871,061

(22) Filed: Jun. 21, 2004

(51) Int. Cl. H05K 7/20; H05K 5/06

(52) U.S. Cl. 174/52.2; 165/185; 165/80.4

(57) ABSTRACT

A hidden radiating fin structure comprises a plurality of metal plates. Between the metal plates are connecting portions, thereby the metal plates can be stacked one on the other using the connecting portions. The connecting portion comprises a plurality of snap pieces and snap holes. The snap piece is formed onto two folded margins of the metal plate at a proper position and retracted to the inside of the folded margins. The snap hole relating to the position of the snap piece is formed on the main unit of the metal plate. The metal plates are hooked to each other using the snap holes and the snap pieces, thereby forming a hidden radiating fin structure that is hidden inside to allow the appearance of a neat and tidy exterior, and prevent itself from being loosened by outside impact.

### BACKGROUND OF THE INVENTION

(a) Field of the Invention

The present invention relates to a hidden radiating fin structure, particularly a stacked type of radiating fin assembly comprising snap holes and snap pieces that are hidden inside.

(b) Description of the Prior Art

As a result of rapid development of computer industry, electronic heat source elements, including chips installed in microprocessors, are generating higher and higher heat while their size is becoming smaller and smaller. To effectively radiate such intensive heat out of the system, and maintain normal performance of the electronic heat source elements at permissible temperature settings, larger areas of radiating fins are generally installed on the surface of electronic heat source elements to assist heat radiation, effectively control proper execution, and extend the service life of electronic heat source elements.

Radiating fins come in three types: aluminum extrusion, compression casting and stacked configuration. Due to restricted machining capacity, the radiating areas of aluminum extrusion and compression casting types are limited. As a result, the cubic measurements and weights of electronic heat source elements generating higher and higher heat have been on the increase accordingly. They can no longer satisfy modern requirements for computer products that must come in lightweight and small size. Therefore, due to their larger radiating areas, the radiating fins of stacked configuration type have gradually been replacing the other two types of radiating fins.

Please refer to FIGS. 1 and 2 that disclose a prior art of stacked type of radiating fins 10a, which are made by punching a plurality of metal plates 11a in specified measurements. The metal plates 11a are made of copper or aluminum. Made in the shape of a “U”, the metal plates 11a each comprising a main unit 12a and two folded margins 13a. The folded margins 13a are parallel to each other and joined to the upper side and lower side of the main unit 12a. The folded margins 13a is perpendicular to the main unit 12a. On the folded margins 13a are connecting portions 14a. Using the connecting portions 14a, the metal plates 11a are joined and stacked to form a radiating fin assembly 10a with specified measurements.

The connecting portion 14a comprising a plurality of snap holes 15a and matching snap pieces 16a. The snap holes 15a are located on the folded margins 13a. Using the snap holes 15a and the snap pieces 16a interlocking each other, the metal plates 11a are stacked and joined to form the radiating fin assembly 10a. By gluing or welding the folded margin 13a at the lower side of the main unit 12a to a radiating substrate (not shown in diagram), and then fitting the radiating substrate onto a surface of a electronic heat source element, the radiating fin assembly 10a is capable of assisting heat radiation.

However, after the aforementioned prior art of radiating fin assembly is assembled, the connecting portion 14a comprising snap holes 15a and snap pieces 16a are exposed to the outside, which result in bad effects on its appearance, and loosening of the connecting portion 14a when subjected to an outside impact, and consequently the entire radiating fin assembly would fall apart.

Therefore, the above prior art of radiating fin assembly does have inconveniences and shortcomings that need improvement.

To seek improvement on the above shortcomings, the inventor has come up with the present invention with reasonable design and effective improvement.

### SUMMARY OF THE INVENTION

The primary objective of the invention is to provide a hidden radiating fin structure, hiding the connecting portions between the metal plates, ensuring its outside appearance from bad effects, giving a neat exterior and excellent quality tone, while the connecting portions hidden inside will not be loosened by outside impact, thereby avoiding the entire radiating fin assembly from falling apart.

To achieve the above objective, the present invention provides a hidden radiating fin structure, comprising a plurality of metal plates, the metal plates each including a main unit and two folded margins. Between the metal plates are connecting portions. The connecting portion comprises a plurality of snap pieces and snap holes. The snap piece is formed onto two folded margins of the metal plate at a proper position and retracted to the inside of the folded margins. The snap hole relating to the position of the snap piece is formed on the main unit of the metal plate. The metal plates are interlocked by the snap holes and snap pieces, thereby the metal plates are stacked to form a radiating fin assembly.

For better understanding of the characteristics and technical approach of the present invention, please refer to the detailed description and drawings as follows. The drawings provided, however, are for reference and description only, and shall not be based to restrict the present invention.

### BRIEF DESCRIPTION OF DRAWINGS

The following and other features and advantages of the present invention will be more easily understood from the following detailed description and the accompanying drawings, in which,

FIG. 1 is a perspective, disassembled view of a prior art of radiating fins.

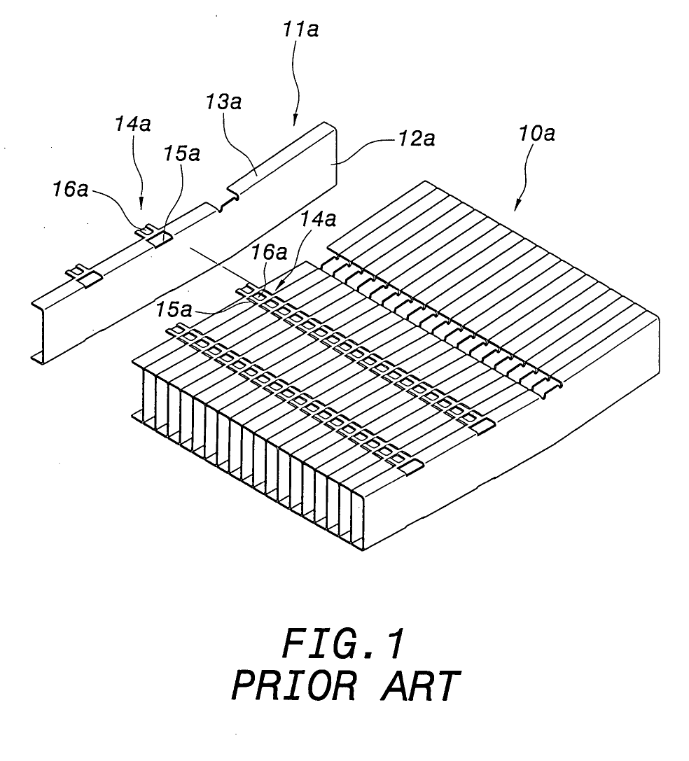

FIG. 2 is a section view of a prior art of radiating fins.

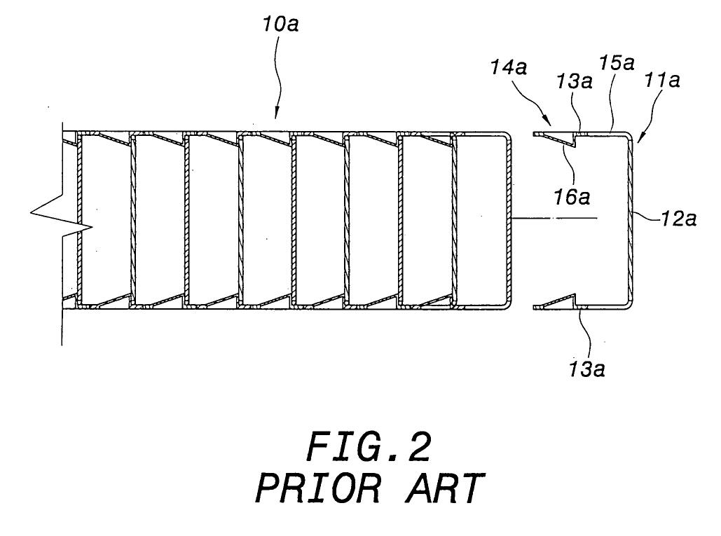

FIG. 3 is a perspective, disassembled view of the invention.

FIG. 4 is a perspective, assembled view of the invention.

FIG. 5 is a section view of the invention.

### DETAILED DESCRIPTION OF PREFERRED EMBODIMENTS

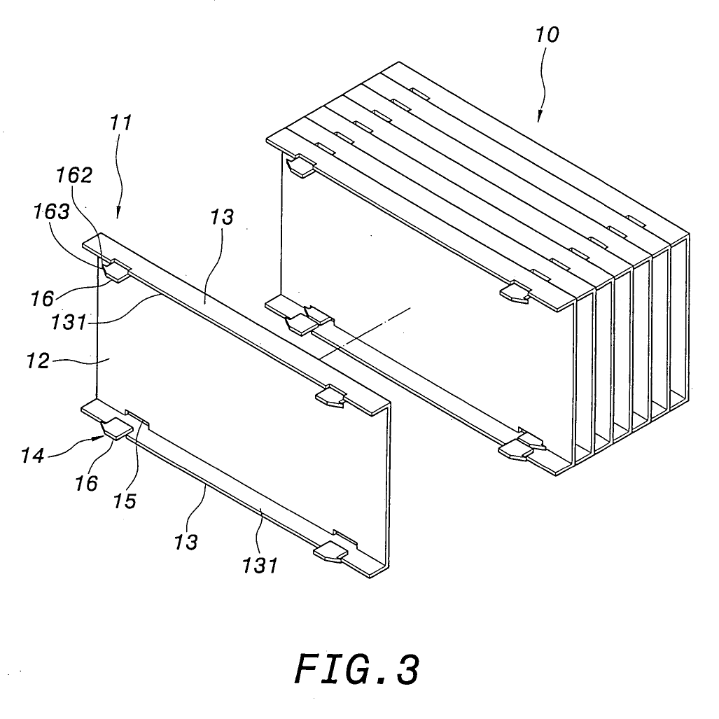

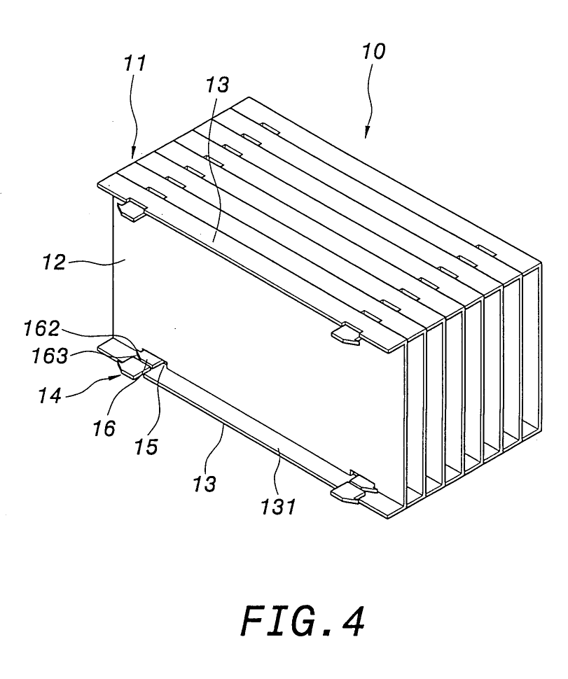

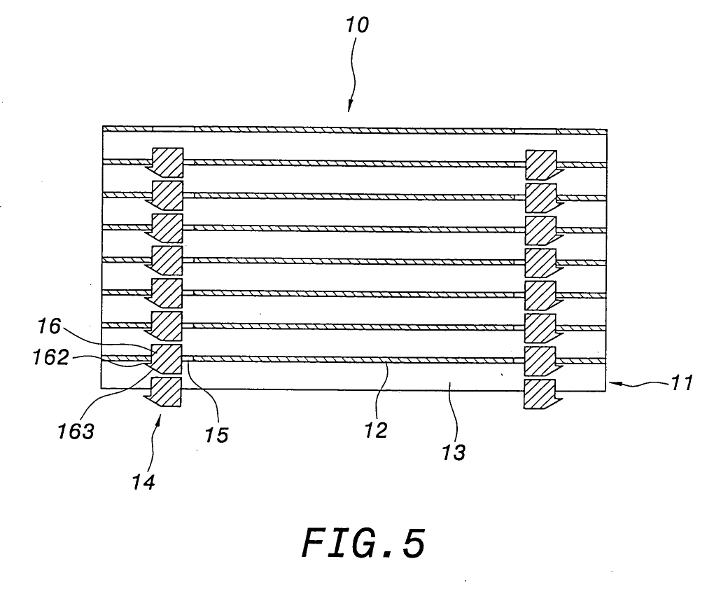

As shown in FIGS. 3, 4 and 5, the present invention provides a hidden radiating fin structure, the radiating fins 10 are made by punching a plurality of metal plates 11 in specified measurements. The metal plate 11 is made of material with excellent heat conducting property, such as copper or aluminum. The metal plate 11 is punched in the shape of a “U”. Of course, the metal plate 11 can be punched optionally in other shapes. Each of the metal plates 11 includes a main unit 12 and two folded margins 13. The two folded margins 13 are parallel to each other and are joined to an upper side and a lower side of the main unit 12. The two folded margins 13 are perpendicular to the main unit 12. Since the aforementioned radiating fins are the same as the prior art, they need no elaboration here.

The present invention is characterized in a connecting portion 14 that is hidden between the metal plates 11. Using the connecting portion 14, the metal plates 11 are joined and stacked one on the other to form a specified size of radiating fins 10 stacking together. Besides, the connecting portions 14 are invisible because they are hidden inside.

The connecting portion 14 comprises a plurality of snap pieces 16 and matching snap holes 15. The snap pieces 16 are formed on the folded margins 13 at proper positions. The snap pieces 16 are protruding from the folded margins 13. The snap pieces 16 are retracted to the insides of the folded margins 13 and located above the main unit 12. The snap piece 16 each has a protruded hook 162 at one side, and at the front of the hook 162 is a guiding angle 163. The snap holes 15 relating to the positions of the snap pieces 16 are formed on the main unit 12. The width of the snap hole 15 is the same or slightly larger than the width of the snap piece 16. In the preferred embodiment, the snap holes 15 are flattened retangular openings and formed on the left side and right side in the vicinity of the main unit 12.

The metal plates 11 are hooked to each other by the snap pieces 16 and snap holes 15. By stacking them continuously one on the other, the stacked metal plates 11 form the radiating fins 10 in a way that, the snap piece 16 of the metal plate 11 is inserted in the snap hole 15 of another metal plate 11. Since the snap piece 16 has a guiding angle 163, which leads the snap piece 16 to smoothly insert into the snap hole 15. After the snap piece 16 is inserted in place in the snap hole 15, the hook 162 of the snap piece 16 hooks onto the edge of the snap hole 15, thereby the metal plates 11 are stacked on each other and joined by the connecting portions 14, to form the present invention of hidden radiating fin structure.

By gluing or welding the folded margin 13 at the lower part of the main unit 12 to a radiating substrate (not shown in diagram), then fastening the radiating substrate onto a surface of an electronic heat source element, or, by gluing the folded margin 13 at the lower part of the main unit 12 directly onto an electronic heat source element, the radiating fins 10 are capable of assisting heat radiation.

In the present invention, the snap hole 15 of the connecting portion 14 is located on the main unit 12, instead of on the folded margin 13, and the snap piece 16 is retracted to the inside of the folded margin 13, to match the snap hole 15. So after the assembly, the connection portion 14 comprising the snap hole 15 and the snap piece 16 are hidden inside. The connecting portion 14 is invisible from outside, so its outer appearance is not affected. So, its appearance looks neat and of good quality tone. Furthermore, the connecting portions 14 hidden inside are safe from being loosened by outside impact, thus avoiding the radiating fin assembly from falling apart.

To conclude, the present invention is an unprecedented innovation with industrial applicability, novelty and inventive step. Having satisfied the requirements for a patent right, this application is filed according to the patent law. Your favorable consideration will be appreciated.

Although the present invention has been illustrated and described with reference to the preferred embodiment thereof, it should be understood that it is in no way limited to the details of such embodiment but is capable of numerous modifications within the scope of the appended claims.

1. A hidden radiating fin structure, comprising a plurality of metal plates, said metal plates each having a main unit and two folded margins, said metal plates each defining a connecting portion therebetween, said connecting portion having a plurality of snap pieces and corresponding snap holes, the snap pieces formed onto two folded margins at proper positions and protruding from the folded margins so that the snap pieces being retracted to the insides of the folded margins and located above the main unit, the snap holes relating to the positions of the snap pieces formed on the main unit, the metal plates hooked together through the snap holes and the snap pieces thereof, thereby the metal plates are stacked to form the radiating fin structure.

2. The hidden radiating fin structure as claimed in claim 1, wherein said main unit has two sides perpendicularly extended with said two folded margins, one of said two folded margins is paralleled to the other.

3. The hidden radiating fin structure as claimed in claim 1, wherein the snap holes are adjacent to a left side and a right side of the main unit.

4. The hidden radiating fin structure as claimed in claim 1, wherein an external side surface of each of the snap pieces and the inside surface of each of the folded margins are arranged on a coplanarity.

5. The hidden radiating fin structure as claimed in claim 1, wherein the width of the snap holes is the same or slightly larger than the width of the snap piece.
